(19) United States
(12) Patent Application Publication
(10) Pub. No.: US 2012/0153132 A1
(43) Pub. Date: Jun. 21, 2012

(54) ELEMENT CARRIER AND LIGHT RECEIVING MODULE

(75) Inventors: Yuichiro Horiguchi, Chiyoda-ku (JP); Kohei Sugihara, Chiyoda-ku (JP); Yasuhisa Shimakura, Chiyoda-ku (JP); Toshiharu Miyahara, Chiyoda-ku (JP); Satoshi Kajiya, Chiyoda-ku (JP); Satoshi Nishikawa, Chiyoda-ku (JP); Eiji Yagyu, Chiyoda-ku (JP)

(73) Assignee: MITSUBISHI ELECTRIC CORPORATION, Chiyoda-ku (JP)

(21) Appl. No.: 13/298,702

(22) Filed: Nov. 17, 2011

(30) Foreign Application Priority Data
Dec. 15, 2010 (JP) 2010-279199

(51) Int. Cl. H03F 1/00; H05K 1/00

(52) U.S. Cl. 250/214 A; 361/748

(57) ABSTRACT

An element carrier has a mounting surface where at least one element outputting a high-frequency signal is disposed. A first dielectric layer has a first side surface partially forming the mounting surface and a first main surface connecting to the first side surface and extending in an intersecting direction intersecting with the mounting surface. A first wiring pattern is provided on the first main surface and extends from the first side surface. A second dielectric layer has a second side surface partially forming the mounting surface and a second main surface connecting to the second side surface and extending in the intersecting direction, and is provided on a part of the first main surface of the first dielectric layer where the first wiring pattern is provided. A second wiring pattern is provided on the second main surface of the second dielectric layer and extends from the second side surface.

### BACKGROUND OF THE INVENTION

1. Field of the Invention

The present invention relates to an element carrier and a light receiving module using the same.

2. Description of the Background Art

A light receiving module has a light receiving element and an amplifying element. The light receiving element is an element converting a light intensity signal from outside into a weak electrical signal. The amplifying element is an element amplifying this weak electrical signal and outputting the amplified signal as a high-frequency signal having sufficient intensity. A multichannel-type light receiving module having a plurality of light receiving circuits housed in one package has been demanded in recent years. By using the multichannel-type light receiving module particularly in a phase modulation method, that is, a method for receiving a plurality of light intensity signals outputted from an interferometer in a balanced manner, reduction in space occupied by the light receiving module can be achieved.

Japanese Patent No. 4001744 discloses a light receiving device as a light receiving module. This light receiving device has a carrier, a light receiving element, a preamplifier, first and second high-frequency terminals, first and second broadside-coupled differential lines, first and second differential vertical vias, and first and second differential lines. The carrier has a chip mounting surface. The light receiving element is mounted on the chip mounting surface. The preamplifier is connected to the light receiving element and is mounted on the chip mounting surface. The first high-frequency terminal is connected to the preamplifier and is mounted on the chip mounting surface. The second high-frequency terminal is connected to the preamplifier and is mounted on the chip mounting surface under the first high-frequency terminal. The first broadside-coupled differential line has one end connected to the first high-frequency terminal and extends horizontally inside the carrier. The second broadside-coupled differential line has one end connected to the first high-frequency terminal and extends horizontally inside the carrier. The first differential vertical via extends downwardly inside the carrier, and has one end connected to the other end of the first broadside-coupled differential line and the other end reaching a plane lying between the first broadside-coupled differential line and the second broadside-coupled differential line. The second differential vertical via extends upwardly inside the carrier, and has one end connected to the other end of the second broadside-coupled differential line and the other end reaching the plane. The first differential line extends horizontally on the plane, and has one end connected to the other end of the first differential vertical via and the other end exposed at a surface opposite to the chip mounting surface. The second differential line extends horizontally on the plane, and has one end connected to the other end of the second differential vertical via and the other end exposed at the surface opposite to the chip mounting surface. A bias supply voltage for driving the light receiving element and the preamplifier is supplied to the light receiving element and the preamplifier by way of a power supply line on the plane.

In the technique disclosed in above-mentioned Japanese Patent No. 4001744, the first and second differential lines (high-frequency transmission path) must be disposed on the plane together with the other wirings such as the power supply line. Therefore, an area where the high-frequency transmission path can be disposed becomes small.

### SUMMARY OF THE INVENTION

The present invention has been made in light of the above-mentioned problems, and an object thereof is to provide an element carrier that allows ensuring of a large area where a high-frequency transmission path can be disposed, and a light receiving module using the element carrier.

An element carrier according to the present invention has a mounting surface where at least one element outputting a high-frequency signal is disposed, and has first and second dielectric layers and first and second wiring patterns. The first dielectric layer has a first side surface partially forming the mounting surface and a first main surface connecting to the first side surface and extending in an intersecting direction intersecting with the mounting surface. The first wiring pattern is provided on the first main surface and extends from the first side surface. The second dielectric layer has a second side surface partially forming the mounting surface and a second main surface connecting to the second side surface and extending in the intersecting direction, and is provided on a part of the first main surface of the first dielectric layer where the first wiring pattern is provided. The second wiring pattern is provided on the second main surface of the second dielectric layer and extends from the second side surface. Either the first or second wiring pattern is a transmission path for the high-frequency signal outputted from the element.

According to the present invention, the first and second wiring patterns are disposed on the first and second main surfaces different from each other, respectively. Therefore, it is possible to ensure a larger area where each of the first and second wiring patterns is disposed, as compared with the case where both the first and second wiring patterns are disposed on the same surface. Therefore, it is possible to ensure a larger area where the high-frequency transmission path, which is either the first or second wiring, is disposed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view schematically showing a light receiving module according to one embodiment of the present invention.

FIG. 2 is a schematic view showing an internal structure of the light receiving module in FIG. 1.

FIG. 3 is a schematic view showing an element carrier portion of the light receiving module as seen from a direction indicated by an arrow III in FIG. 2.

FIG. 4 is a schematic view showing a transmission path for a high-frequency signal provided in the element carrier as well as a light receiving element and an amplifying element mounted on the element carrier as seen from a direction indicated by an arrow IV in FIG. 3.

FIG. 5 is a perspective view schematically showing the element carrier according to one embodiment of the present invention.

FIG. 6 is a schematic view showing a stacked dielectric structure of the element carrier as seen from a direction indicated by an arrow VI in FIG. 5.

FIG. 7 is a schematic view showing a part of the stacked dielectric structure in which layers up to a first dielectric layer are formed as well as a first wiring pattern disposed thereon as seen from the same direction as that in FIG. 6.

FIG. 8 is a cross-sectional view schematically showing a wire bonding step in a method for manufacturing the light receiving module according to one embodiment of the present invention.

FIG. 9A is a cross-sectional view schematically showing a heat transfer path from the amplifying element disposed on a mounting surface according to a first comparative example.

FIG. 9B is a cross-sectional view schematically showing a heat transfer path from the amplifying element disposed on the mounting surface according to a second comparative example.

FIG. 9C is a cross-sectional view schematically showing a heat transfer path from the amplifying element disposed on the mounting surface according to one embodiment of the present invention.

### DESCRIPTION OF THE PREFERRED EMBODIMENTS

An embodiment of the present invention will be described hereinafter with reference to the drawings.

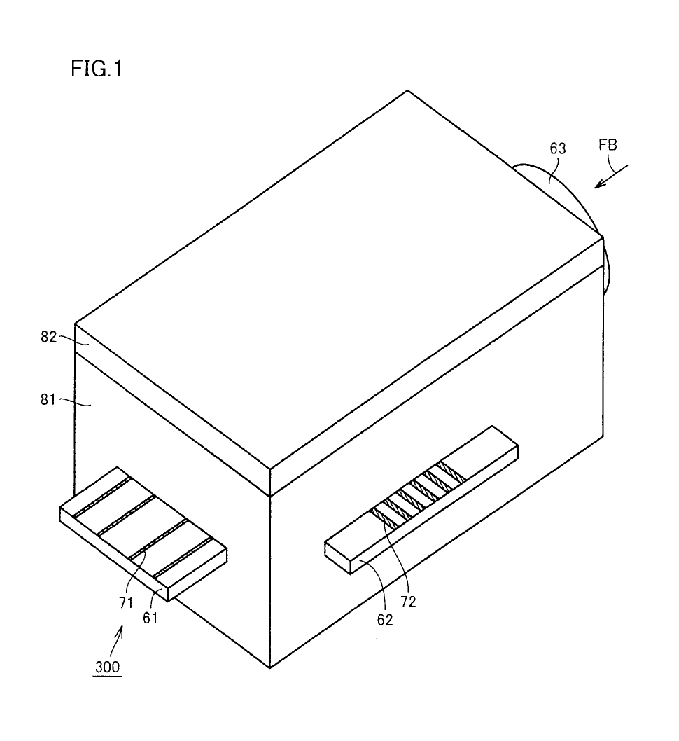

Referring to FIG. 1, a light receiving module 300 according to the present embodiment has terminal plates 61 and 62, an output terminal 71, a wiring terminal 72, a light receiving unit 63, a housing 81, and a lid 82. An upper surface of housing 81 is covered with lid 82. Each of light receiving unit 63 and terminal plate 61 passes through a sidewall of housing 81 at one end and the other end in a length direction of housing 81. Terminal plate 62 protrudes from a side surface of housing 81. Terminal plates 61 and 62 are lower in height than an upper end of housing 81 and higher than a lower end. Output terminal 71 and wiring terminal 72 are formed on terminal plates 61 and 62, respectively.

Light receiving unit 63 gathers a light signal FB from outside on a light receiving element 51. Light signal FB is, for example, a signal light of a plurality of channels exiting from ends of optical fibers attached to light receiving unit 63.

Output terminal 71 is for outputting an electrical high-frequency signal corresponding to this light signal to the outside of light receiving module 300. Wiring terminal 72 is, for example, for supplying power to light receiving module 300.

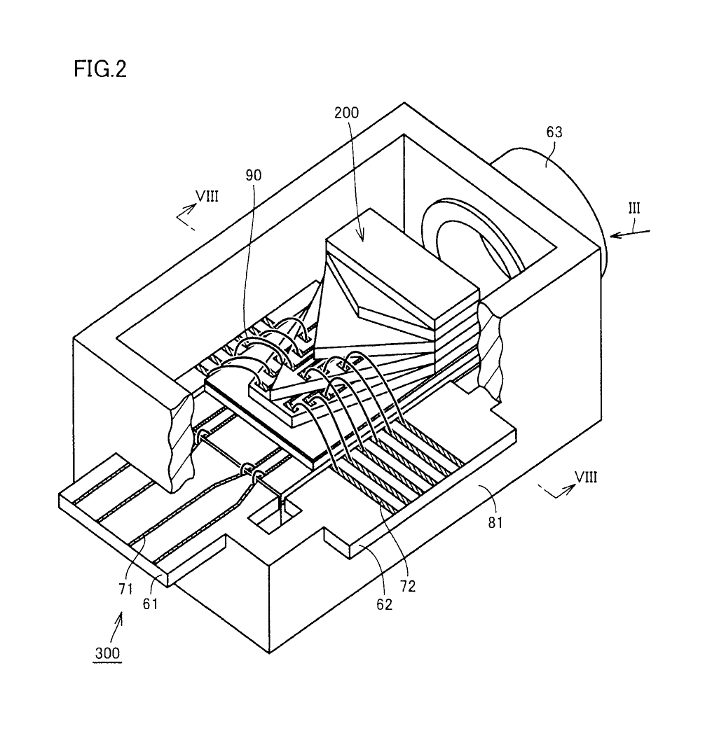

Referring to FIG. 2, light receiving module 300 further has a main body unit 200 inside housing 81. Each of output terminal 71 and wiring terminal 72 is electrically connected to main body unit 200 by a bonding wire 90.

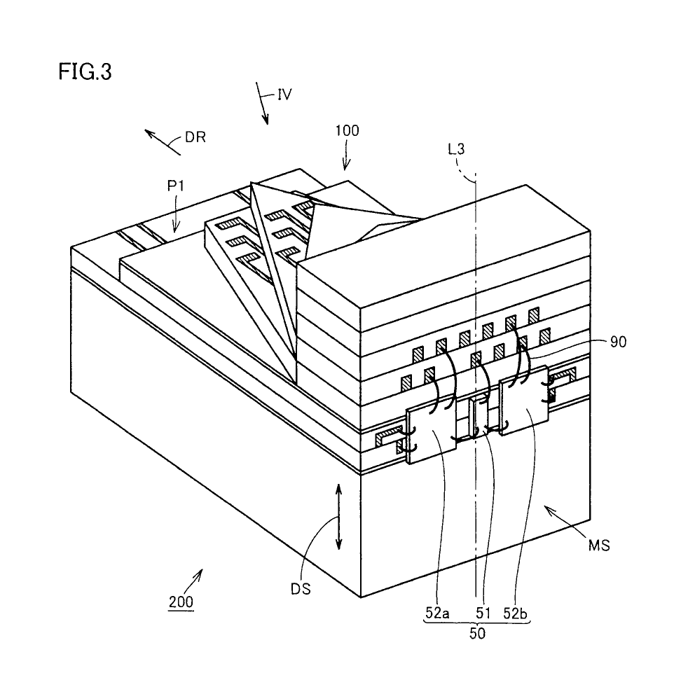

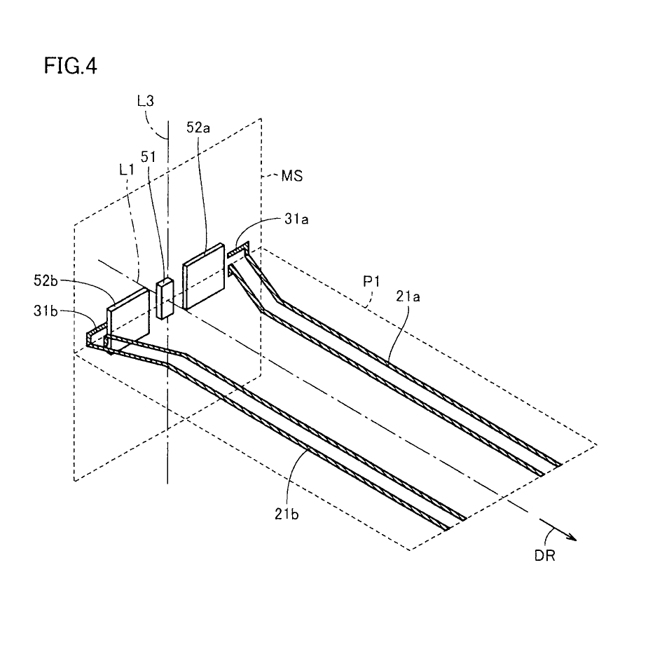

Referring to FIGS. 3 and 4, main body unit 200 has an element carrier 100, an element group 50 and bonding wire 90. Element carrier 100 has a mounting surface MS.

Element group 50 is mounted on mounting surface MS. Element group 50 is electrically connected to element carrier 100 by bonding wire 90. Element group 50 has light receiving element 51 and amplifying elements 52a and 52b (collectively referred to as 52), and outputs the high-frequency signal. Light receiving element 51 is a multichannel-type element, and is a two channel-type element in the present embodiment. Each of amplifying elements 52a and 52b outputs the high-frequency signal by amplifying a signal of each channel of light receiving element 51. Amplifying elements 52a and 52b are disposed to be symmetric with respect to an imaginary straight line L3 (third straight line) following a stacking direction DS (FIG. 3) of a dielectric structure (described in detail later) and passing through light receiving element 51 on mounting surface MS.

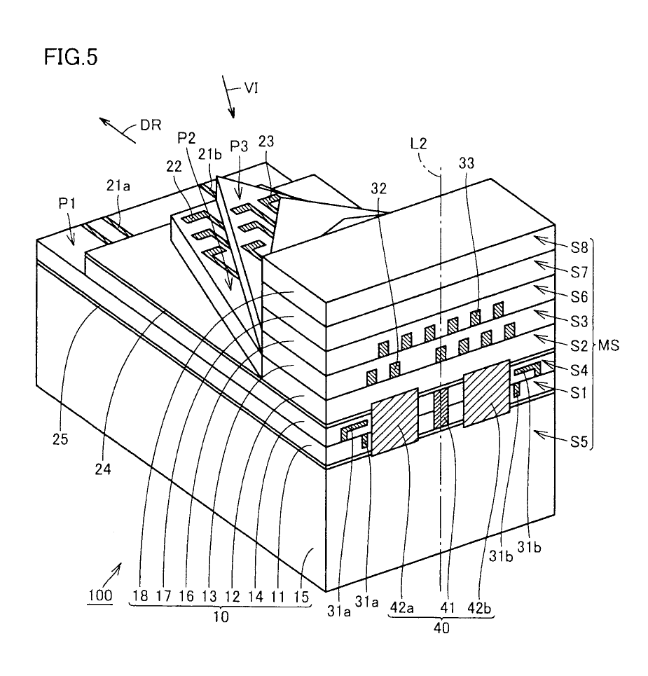

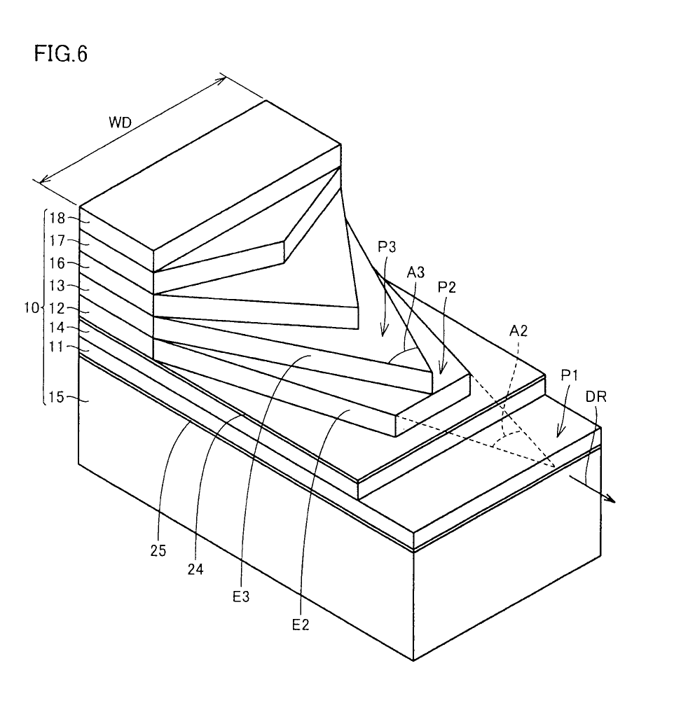

Referring to FIGS. 5 and 6, element carrier 100 has a stacked dielectric structure 10, high-frequency transmission paths (first wiring pattern) 21a and 21b, a wiring pattern 22 (second wiring pattern), a wiring pattern 23, an upper shield layer 24 (first conductive layer), a lower shield layer 25 (second conductive layer), a mounting unit 40, mounting surface wirings 31a and 31b, and electrode pads 32 and 33. Stacked dielectric structure 10 has dielectric layers 11 to 18. A width WD (FIG. 6) of stacked dielectric structure 10 is approximately 5 mm, for example.

Dielectric layer 11 (first dielectric layer) has a side surface S1 (first side surface) partially forming mounting surface MS and a main surface P1 (first main surface) connecting to side surface S1 and extending in an intersecting direction DR intersecting with mounting surface MS. Dielectric layer 11 and dielectric layers 14, 12, 13, 16, 17, and 18 located on dielectric layer 11 of stacked dielectric structure 10 have a stepped structure in this order.

High-frequency transmission paths 21a and 21b are provided on main surface P1 and extends from side surface S1 of dielectric layer 11. Each of high-frequency transmission paths 21a and 21b is a transmission path for the high-frequency signal, and is a differential line formed of a pair of wiring patterns running in parallel with each other as seen in a plane. Therefore, the two-channel high-frequency signal can be transmitted through high-frequency transmission paths 21a and 21b (collectively referred to as 21).

Dielectric layer 12 (second dielectric layer) has a side surface S2 (second side surface) partially forming mounting surface MS and a main surface P2 (second main surface) connecting to side surface S2 and extending in intersecting direction DR, and is provided on a part of main surface P1 of dielectric layer 11 where high-frequency transmission path 21 is provided. On the opposite side of side surface S2, dielectric layer 12 has an end E2 (second end) converging at an angle A2. Therefore, main surface P2 of end E2 has a width that decreases with increasing distance from mounting surface MS.

Wiring pattern 22 is provided on main surface P2 of dielectric layer 12 and extends from side surface S2. Preferably, wiring pattern 22 is not the transmission path for the high-frequency signal but a pattern for supplying power to element group 50, for example.

Dielectric layer 13 (third dielectric layer) has a side surface S3 (third side surface) partially forming mounting surface MS and a main surface P3 (third main surface) connecting to side surface S3 and extending in intersecting direction DR, and is provided on a part of main surface P2 of dielectric layer 12 where wiring pattern 22 is provided. On the opposite side of side surface S3, dielectric layer 13 has an end E3 (first end) converging at an angle A3. Therefore, dielectric layer 13 has end E3 (first end) on the opposite side of side surface S3 and main surface P3 of end E3 has a width that decreases with increasing distance from mounting surface MS. Angle A3 is larger than angle A2, and thus, the width of main surface P3 of end E3 decreases more sharply with increasing distance from mounting surface MS, than the width of main surface P2 of end E2. As a result, main surface P2 has a portion located outward in a width direction beyond end E3 as seen from the stacking direction of stacked dielectric structure 10 (in the figure, as seen from above), and the electrode pad of wiring pattern 22 is disposed on this portion as shown in FIG. 5.

Dielectric layer 14 is provided between high-frequency transmission path 21 and dielectric layer 12. Dielectric layer 14 has a side surface S4 partially forming mounting surface MS.

Dielectric layer 15 serves as a base of stacked dielectric structure 10 and has a side surface S5 partially forming mounting surface MS. Dielectric layers 16 to 18 are provided on dielectric layer 13 in this order. Dielectric layers 16 to 18 have side surfaces S6 to S8 partially forming mounting surface MS, respectively.

Upper shield layer 24 is provided between dielectric layer 12 and dielectric layer 14, and covers high-frequency transmission path 21 with dielectric layer 14 interposed therebetween. Upper shield layer 24 is set to a ground potential when element carrier 100 is actually used. Lower shield layer 25 covers the first wiring pattern with dielectric layer 11 interposed therebetween. Lower shield layer 25 is set to a ground potential when element carrier 100 is actually used.

Impedance matching is preferably implemented between high-frequency transmission path 21 and each of upper shield layer 24 and lower shield layer 25, thereby forming a strip line together with high-frequency transmission path 21. As a result, a loss in high-frequency transmission path 21 can be reduced.

Mounting unit 40 is formed of a conductor and is provided on mounting surface MS. Mounting unit 40 has mounting areas 41, 42a and 42b to mount element group 50. Mounting area 41 is an area where light receiving element 51 (FIG. 3) is mounted, and mounting areas 42a and 42b are areas where amplifying elements 52a and 52b (FIG. 3) are mounted, respectively. Mounting unit 40 is disposed to be symmetric with respect to an imaginary straight line L2 (second straight line) along the stacking direction of stacked dielectric structure 10 on mounting surface MS. As a result, on mounting surface MS, the transmission path for the high-frequency signal from amplifying element 52a can be matched with the transmission path for the high-frequency signal from amplifying element 52b in terms of the high-frequency property. In particular, since these paths have the same length, a skew shift between these paths can be suppressed.

Electrode pads 32 and 33 are, for example, electrodes for supplying power to amplifying elements 52a and 52b (FIG. 3), respectively, via bonding wire 90.

Mounting surface wirings 31a and 31b connect to high-frequency transmission paths 21a and 21b, respectively. Each of mounting surface wirings 31a and 31b has a portion extending in the stacking direction of stacked dielectric structure 10. As a result, mounting surface wirings 31a and 31b can be provided at a position suitable for connection by bonding wire 90 to amplifying elements 52a and 52b (FIG. 3), respectively.

If this optimization of the position is implemented by a through hole in stacked dielectric structure 10, impedance matching at the through hole portion is generally difficult and a mode discontinuous point is formed. Therefore, a loss in transmission of the high-frequency signal increases. This increase in the loss is particularly serious when the high-frequency signal has a frequency of 10 GHz or more. In contrast, if this optimization of the position is implemented by mounting surface wirings 31a and 31b provided on the mounting surface as in the present embodiment, impedance matching becomes easy. In order to implement this impedance matching, mounting surface wirings 31a and 31b may, for example, be coplanar lines.

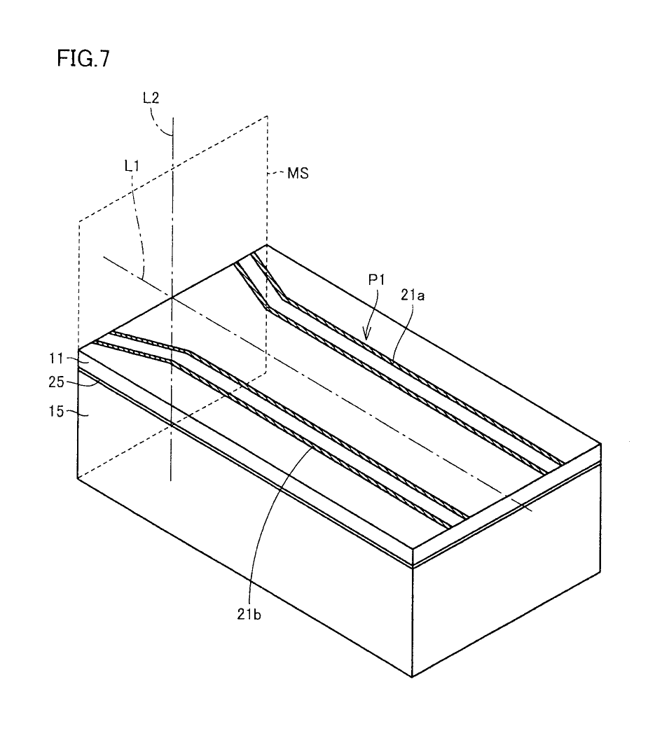

Referring to FIG. 7, high-frequency transmission path 21 is disposed to be symmetric with respect to an imaginary straight line L1 (first straight line) along intersecting direction DR. As a result, high-frequency transmission paths 21a and 21b are line symmetric, and thus, high-frequency transmission path 21a can be matched with high-frequency transmission path 21b in terms of the high-frequency property. In particular, since these paths have the same length, a skew shift between these paths can be suppressed.

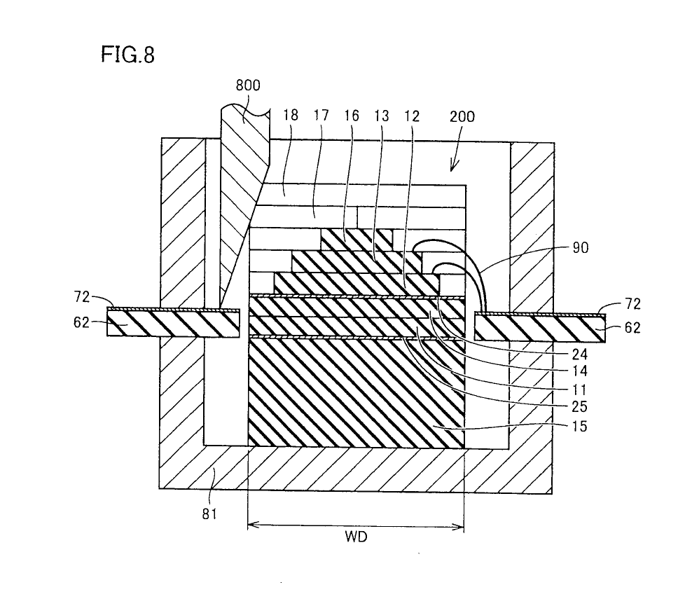

A process of wire bonding between wiring terminal 72 attached to housing 81 and main body unit 200 will be described with reference to FIG. 8. In order to provide bonding wire 90, a capillary 800 is inserted onto wiring terminal 72. In other words, capillary 800 is inserted to be adjacent to end E3 (FIG. 6) of dielectric layer 13 in the width direction and to be adjacent to end E2 (FIG. 6) of dielectric layer 12 in the width direction. Since the width of end E3 is narrower than width WD (FIG. 6) of mounting surface MS, sufficient space can be ensured between dielectric layer 13 and capillary 800. In addition, since the width of end E2 is narrower than width WD (FIG. 6) of mounting surface MS, sufficient space can be ensured between dielectric layer 12 and capillary 800. This space has a dimension of approximately 1 to 2 mm, for example.

Next, a description will be given to a relationship between a heat transfer path of heat generated by amplifying element 52 and the shape of the stacked dielectric structure.

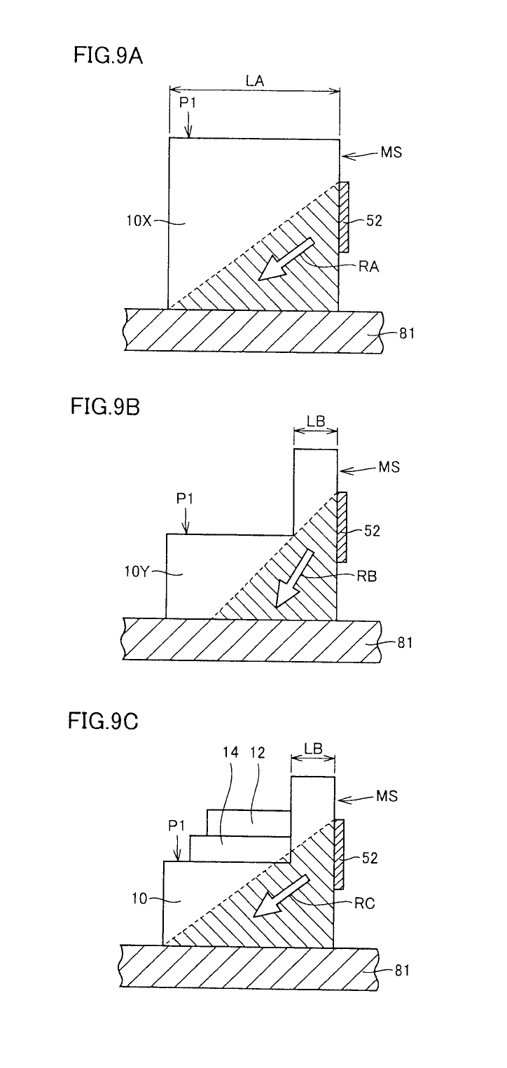

Referring to FIG. 9A, a stacked dielectric structure 10X according to a first comparative example has a rectangular parallelepiped shape having a length LA, unlike stacked dielectric structure 10 according to the present embodiment. In this case, a large cross-sectional area of the heat transfer path for transferring heat generated by amplifying element 52 through a bottom portion of stacked dielectric structure 10X to housing 81 is ensured as indicated by an arrow RA.

In the present comparative example, however, both high-frequency transmission path 21 and wiring pattern 22 must be disposed on main surface P1, and thus, a large area where high-frequency transmission path 21 is disposed cannot be ensured. In addition, the position of main surface P1 is limited to the position of an upper surface of stacked dielectric structure 10X. In order to minimize the size of housing 81, output terminal 71 (FIGS. 1 and 2) must be disposed at an upper end of housing 81. Generally, such disposition of output terminal 71 is not preferable for attaching light receiving module 300. This problem itself is solved by using a long bonding wire extending in the height direction. Such wire bonding is, however, difficult because the capillary must be inserted into narrow space between stacked dielectric structure 10X and housing 81. Even if wire bonding is possible, it is not preferable to apply the long bonding wire to the transmission path for the high-frequency signal. Based on the above, when stacked dielectric structure 10X is used, the height position of the upper surface thereof must be matched with the height position of output terminal 71, and in order to do so, a larger housing must be used. As a result, the light receiving module increases in size.

Referring to FIG. 9B, a stacked dielectric structure 10Y according to a second comparative example has a shape obtained by removing, in the form of a rectangular parallelepiped, an upper portion on the opposite side of mounting surface MS of above-mentioned stacked dielectric structure 10X. In this case, a length LB of the upper portion of stacked dielectric structure 10Y is shorter than length LA. As a result, the cross-sectional area of the heat transfer path for transferring heat generated by amplifying element 52 through a bottom portion of stacked dielectric structure 10Y to housing 81 becomes smaller as indicated by an arrow RB than the cross-sectional area in FIG. 9A (arrow RA). Therefore, in the present comparative example, heat from amplifying element 52 is not easily released from stacked dielectric structure 10Y. In other words, the heat release property from mounting surface MS deteriorates.

A simulation was carried out to verify deterioration of the heat release property in stacked dielectric structure 10Y. As for stacked dielectric structure 10X (FIG. 9A), when length LA was 6 mm, the electric power consumption of amplifying element 52 was 0.3 W, and stacked dielectric structure 10X was made of alumina, a rear surface of amplifying element 52 had a temperature of 81° C. In contrast, a similar simulation was carried out on stacked dielectric structure 10Y (FIG. 9B), with length LB set to 2 mm. Then, the rear surface of amplifying element 52 had a temperature of 87° C. This result shows that the heat release property from mounting surface MS is lower in stacked dielectric structure 10Y than in stacked dielectric structure 10X.

FIG. 9C shows stacked dielectric structure 10 according to the present embodiment in a simplified manner. Stacked dielectric structure 10 has dielectric layer 14 having a length shorter than maximum length LA (FIG. 9A) of stacked dielectric structure 10 and longer than length LB of the upper portion of stacked dielectric structure 10. As a result, a large cross-sectional area of the heat transfer path is ensured as indicated by an arrow RC, almost similarly to the cross-sectional area in the first comparative example (arrow RA). Therefore, heat from the amplifying element is easily released from stacked dielectric structure 10. In other words, the heat release property from mounting surface MS becomes high.

It is to be noted that this advantageous effect can be obtained due to dielectric layer 12 even if dielectric layer 14 is not provided.

According to element carrier 100 in the present embodiment, high-frequency transmission path 21 is disposed on main surface P1, and the other wiring patterns 22 and 23 are disposed on the surfaces different from main surface P1. Therefore, a larger area where high-frequency transmission path 21 is disposed can be ensured as compared with the case where both high-frequency transmission path 21 and wiring patterns 22 and 23 are disposed on main surface P1. As a result, larger spacing can be ensured between high-frequency transmission paths 21a and 21b (FIG. 4), and thus, crosstalk noise between these paths can be easily suppressed to, for example, —20 dB or less.

It is to be noted that as a modification of the above-mentioned present embodiment, wiring pattern 22 (second wiring pattern) may be used as the transmission path for the high-frequency signal and high-frequency transmission path 21 may be used for the purpose other than the transmission path for the high-frequency signal. In addition, the layers other than first and second dielectric layers 11 and 12 of stacked dielectric structure 10 may not be provided. In addition, a light receiving element having the larger number of channels or a single channel-type light receiving element may be used instead of two channel-type light receiving element 51. In addition, a plurality of light receiving elements may be used instead of one light receiving element 51. In addition, although the strip line has been described as the preferable high-frequency transmission path, the coplanar line may be used instead of the strip line.

Instead of end E2 (FIG. 6) formed by two straight lines converging at angle A2 as seen in a plane, an end having an outer edge formed by a larger number of straight lines or an end having a curved outer edge may be used. The same is also applied to end E3. For example, in order to configure the end having the outer edge formed by a larger number of straight lines, T-shaped second main surface P2 having width WD from mounting surface MS to a predetermined distance and a width narrower than width WD on the DR side beyond this predetermined distance may be provided instead of converging end E2.

In addition, a further element may be mounted on mounting surface MS in addition to light receiving element 51 and amplifying element 52, and a capacitor, for example, may be mounted. Respective elements on mounting surface MS are disposed with appropriate spacing.

Although the present invention has been described and illustrated in detail, it is clearly understood that the same is by way of illustration and example only and is not to be taken by way of limitation, the scope of the present invention being interpreted by the terms of the appended claims.

What is claimed is:

1. An element carrier having a mounting surface where at least one element outputting a high-frequency signal is disposed, comprising:
a first dielectric layer having a first side surface partially forming said mounting surface and a first main surface connecting to said first side surface and extending in an intersecting direction intersecting with said mounting surface;
a first wiring pattern provided on said first main surface and extending from said first side surface;
a second dielectric layer having a second side surface partially forming said mounting surface and a second main surface connecting to said second side surface and extending in said intersecting direction, and provided on a part of said first main surface of said first dielectric layer where said first wiring pattern is provided;
a second wiring pattern provided on said second main surface of said second dielectric layer and extending from said second side surface; and
a third dielectric layer having a third side surface partially forming said mounting surface and a third main surface connecting to said third side surface and extending in said intersecting direction, and provided on a part of said second main surface of said second dielectric layer where said second wiring pattern is provided,
either said first or second wiring pattern being a transmission path for said high-frequency signal outputted from said element.

2. The element carrier according to claim 1, wherein
said first wiring pattern is the transmission path for said high-frequency signal.

3. The element carrier according to claim 1, wherein
said third dielectric layer has a first end on an opposite side of said third side surface, and said third main surface of said first end has a width that decreases with increasing distance from said mounting surface.

4. The element carrier according to claim 3, wherein
said second wiring pattern includes a portion disposed outward in a width direction beyond said first end as seen from a stacking direction of said first to third dielectric layers.

5. The element carrier according to claim 3, wherein
said second dielectric layer has a second end on an opposite side of said second side surface, and said second main surface of said second end has a width that decreases with increasing distance from said mounting surface, and
the width of said third main surface of said first end decreases more sharply with increasing distance from said mounting surface, than the width of said second main surface of said second end.

6. The element carrier according to claim 1, further comprising:
a fourth dielectric layer provided between said first wiring pattern and said second dielectric layer; and
a first conductive layer provided between said second dielectric layer and said fourth dielectric layer, covering said first wiring pattern with said fourth dielectric layer interposed therebetween, and set to a ground potential.

7. The element carrier according to claim 1, further comprising
a second conductive layer covering said first wiring pattern with said first dielectric layer interposed therebetween, and set to a ground potential.

8. The element carrier according to claim 1, wherein
said first wiring pattern is disposed to be symmetric with respect to an imaginary first straight line along said intersecting direction.

9. The element carrier according to claim 1, further comprising
a mounting unit formed of a conductor, for mounting said at least one element on said mounting surface.

10. The element carrier according to claim 9, wherein
said mounting unit is disposed to be symmetric with respect to an imaginary second straight line along a stacking direction of said first to third dielectric layers on said mounting surface.

11. A light receiving module, comprising:
an element carrier having a mounting surface where at least one element outputting a high-frequency signal is disposed,
said element carrier including:
a first dielectric layer having a first side surface partially forming said mounting surface and a first main surface connecting to said first side surface and extending in an intersecting direction intersecting with said mounting surface;
a first wiring pattern provided on said first main surface and extending from said first side surface;
a second dielectric layer having a second side surface partially forming said mounting surface and a second main surface connecting to said second side surface and extending in said intersecting direction, and provided on a part of said first main surface of said first dielectric layer where said first wiring pattern is provided;
a second wiring pattern provided on said second main surface of said second dielectric layer and extending from said second side surface; and
a third dielectric layer having a third side surface partially forming said mounting surface and a third main surface connecting to said third side surface and extending in said intersecting direction, and provided on a part of said second main surface of said second dielectric layer where said second wiring pattern is provided,
either said first or second wiring pattern being a transmission path for said high-frequency signal outputted from said element,
said light receiving module further comprising:
a light receiving element included in said at least one element and disposed on said mounting surface of said element carrier; and
at least one amplifying element included in said at least one element, disposed on said mounting surface of said element carrier, and outputting said high-frequency signal by amplifying a signal from said light receiving element.

12. The light receiving module according to claim 11, wherein
said first wiring pattern is the transmission path for said high-frequency signal.

13. The light receiving module according to claim 11, wherein
said third dielectric layer has a first end on an opposite side of said third side surface, and said third main surface of said first end has a width that decreases with increasing distance from said mounting surface.

14. The light receiving module according to claim 13, wherein
said second wiring pattern includes a portion disposed outward in a width direction beyond said first end as seen from a stacking direction of said first to third dielectric layers.

15. The light receiving module according to claim 13, wherein
said second dielectric layer has a second end on an opposite side of said second side surface, and said second main surface of said second end has a width that decreases with increasing distance from said mounting surface, and
the width of said third main surface of said first end decreases more sharply with increasing distance from said mounting surface, than the width of said second main surface of said second end.

16. The light receiving module according to claim 11, further comprising:
a fourth dielectric layer provided between said first wiring pattern and said second dielectric layer; and
a first conductive layer provided between said second dielectric layer and said fourth dielectric layer, covering said first wiring pattern with said fourth dielectric layer interposed therebetween, and set to a ground potential.

17. The light receiving module according to claim 11, further comprising
a second conductive layer covering said first wiring pattern with said first dielectric layer interposed therebetween, and set to a ground potential.

18. The light receiving module according to claim 11, wherein
said first wiring pattern is disposed to be symmetric with respect to an imaginary first straight line along said intersecting direction.

19. The light receiving module according to claim 11, further comprising
a mounting unit formed of a conductor, for mounting said at least one element on said mounting surface.

20. The light receiving module according to claim 19, wherein
said mounting unit is disposed to be symmetric with respect to an imaginary second straight line along a stacking direction of said first to third dielectric layers on said mounting surface.
